(19) United States
(12) Patent Application Publication
(10) Pub. No.: US 2018/0122972 A1
(43) Pub. Date: May 3, 2018

(54) SEMI-FLEXIBLE SOLAR MODULE USING CRYSTALINE SOLAR CELLS AND METHOD FOR FABRICATION THEREOF

(71) Applicant: CANADIAN SOLAR SOLUTIONS INC., Guelph (CA)

(72) Inventors: Wenda ZHENG, Guelph (CA); Huirong CAO, Guelph (CA)

(21) Appl. No.: 15/787,260

(22) Filed: Oct. 18, 2017

Related U.S. Application Data
(60) Provisional application No. 62/410,095, filed on Oct. 19, 2016.

(30) Foreign Application Priority Data
Nov. 16, 2016 (CA) 2948560

(51) Int. Cl. H01L 31/049; H01L 31/0443; H01L 31/02; H01L 31/0236; H01L 31/05; H01L 31/18; H01L 31/028; H01L 31/048

(52) U.S. Cl. CPC H01L 31/049; H01L 31/0443; H01L 31/0201; H01L 31/02366; H01L 31/048; H01L 31/1804; H01L 31/028; H01L 31/0481; H01L 31/0508

(57) ABSTRACT

A semi-flexible solar module including: a front layer, for example, ETFE, having an ultra-violet reflecting material; one or more impact cushion layers, for example, EVA; a solar cell layer comprising crystalline silicon solar cells; a support layer comprising a semi-flexible material configured to support the solar cell layer, for example PET; and a back layer, for example, TPT, wherein none of the layers is formed of glass.

### REFERENCE TO RELATED APPLICATIONS

This application claims the benefit of U.S. Provisional Patent Application No. 62/410,095, filed Oct. 19, 2016 and Canadian Patent Application No. 2,948,560, filed Nov. 16, 2016 which are hereby incorporated herein by reference in their entirety.

### FIELD

This present disclosure relates to solar modules and in particular to a semi-flexible solar module using crystalline solar cells and method for fabrication thereof.

### BACKGROUND

Solar cells or photovoltaic cells are electrical devices that convert the energy of light directly into electricity. Conventionally, a plurality of solar cells are includes in a solar module, sometimes known as solar panels. Typically, solar modules include a metal frame, crystalline solar cells and a glass cover plate. Since crystalline solar cells can be fragile, the metal frame and the glass cover plate are intended to protect the crystalline solar cells and generally keep the solar module in predetermined shape.

Recently, flexible solar modules have been developed using thin-film solar cells, which are less fragile than crystalline solar cells and can be rolled up. Thin-film solar modules tend to be smaller and for portable use. One drawback of thin-film solar cells is that they are less efficient at converting light to electricity than crystalline solar cells.

As such, there is a need for a semi-flexible solar module that incorporates crystalline solar cells.

### SUMMARY

In a first aspect the present disclosure provides a solar module including: a front layer having an ultra-violet reflecting material; one or more impact cushion layers; a solar cell layer comprising crystalline silicon solar cells; a support layer comprising a semi-flexible material configured to support the solar cell layer; and a back layer, wherein none of the layers is formed of glass or a material with similar properties as those of glass, including density, flexibility, transparency, brittleness and the like.

In a particular case, the support layer may be transparent and positioned between the front layer and the solar cell layer.

In another particular case, the one or more impact cushion layers also functions as an adhesive layer.

In still another particular case, the solar module may have a second impact cushion layer between the solar cell layer and the support layer.

In yet another particular case, the solar module may have more adhesive layers between the noted layers.

In still yet another particular case, the solar module may include a bypass diode provided to a bus bar on the solar cell layer.

In a particular case, the bypass diode may have a plurality of bypass diodes provided to different bus bars on the solar cell layer.

In another particular case, the thickness of the module is between 3 and 5 mm

In yet another particular case, the solar module may have low profile button connectors.

In still yet another particular case, the front layer includes a surface pattern. In a particular case, the surface pattern has a pattern depth between 0.05 mm to 0.5 mm.

In another aspect there is provided a solar flexible-solar module having: a front layer formed of ETFE; a plurality of impact cushion layers formed of EVA; a solar cell layer formed of crystalline silicon solar cells; a support layer formed of PET; and a back layer formed of TPT.

In a particular case, the support layer is transparent and positioned between the front layer and the solar cell layer.

In another particular case, the plurality of cushion layers also functions as adhesive layers.

In still another particular case, the solar module may include a second impact cushion layer between the solar cell layer and the support layer.

In yet another particular case, the solar module may include one or more adhesive layers between the noted layers.

In still yet another particular case, the solar module includes a bypass diode provided to a bus bar on the solar cell layer.

In a particular case, the bypass diode includes a plurality of bypass diodes provided to different bus bars on the solar cell layer.

In another particular case, the solar module may have a thickness of the module is between 3 mm and 5 mm.

In still another particular case, the solar module further may include low profile button connectors.

In yet another particular case, the front layer of the solar module has a surface pattern.

In a particular case, the surface pattern has a pattern depth between 0.05 mm to 0.5 mm.

In yet another aspect, there is provided a method for applying a pattern sheet to a solar module including: placing solar module layers in order to create the solar module; placing a pattern sheet on a top layer of the solar module; laminating the solar module; and cooling the solar module.

In a particular case, the lamination of the solar module includes: providing a vacuum to the solar module; and providing a retaining period to the solar module.

In another particular case, the retainer period is 10-18 minutes in duration at a press pressure of 60 to 85 kPa and at a temperature of 145° C. to 155° C.

In still another particular case, the cooling of the solar module includes placing a heavy object on top of the pattern sheet to maintain the pattern shape.

Other aspects and features of the present disclosure will become apparent to those ordinarily skilled in the art upon review of the following description of specific embodiments in conjunction with the accompanying figures.

### BRIEF DESCRIPTION OF THE DRAWINGS

Embodiments of the invention will now be described, by way of example only, with reference to the attached drawings, in which:

FIG. 1 illustrates an embodiment of a flexible solar module;

FIG. 2 illustrates another embodiment of a semi-flexible solar module;

FIG. 3 illustrates yet another embodiment of a semi-flexible solar module;

FIG. 4 illustrates still yet another embodiment of a semi-flexible solar module;

FIG. 5 illustrates an example of bus bars and bypass diodes in the semi-flexible solar module of FIG. 1 with junction box;

FIGS. 6A and 6B illustrate an embodiment of connectors for the semi-flexible solar module of FIG. 1 in series and in parallel;

FIG. 7 illustrates an embodiment of a junction box for use with the connectors of FIG. 5;

FIG. 8 illustrates a close up of a bypass diode laminated in a solar module;

FIG. 9 illustrates an example of a surface pattern applied to a front layer of the semi-flexible solar module of FIG. 1 from a top view and side view; and

FIG. 10 is a flow chart of a method for applying a pattern to a surface for a solar module.

### DETAILED DESCRIPTION

Generally, the disclosure provides for a semi-flexible solar module using crystalline solar cells. The disclosure also relates to an electrical connection device for a semi-flexible solar module and a surface pattern for a semi-flexible solar module. Allowing for some flexibility, the solar module is intended to have a greater range of uses than a rigid solar module. The semi-flexible solar module is also intended to weigh less than a conventional solar module.

The semi-flexible module is intended to be easily cold bent to conform to the curvature at the location of installation. The solar module is intended to be light weight, so transportation becomes cheaper and facilitates its assembly. Further, the surface finish may allow a self-cleaning behavior because it is non-stick material and may minimize surface tension due to its texture. The solar module may be affixed with adhesive or screws.

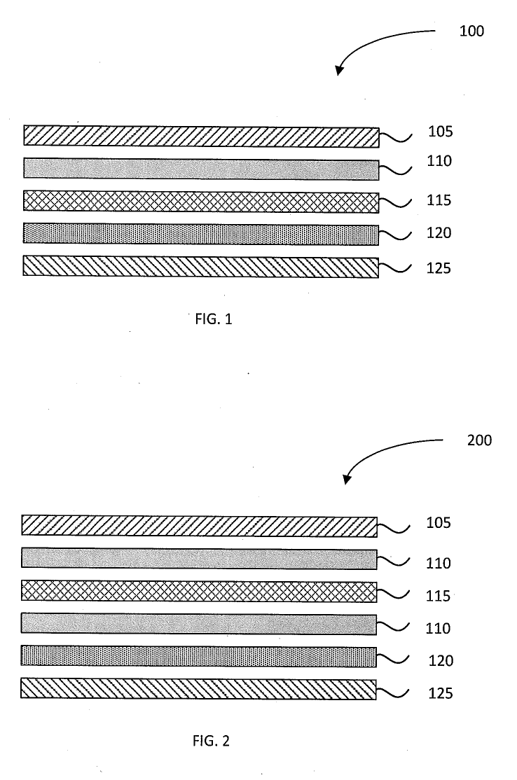

FIG. 1 illustrates an embodiment of a semi-flexible solar module 100. In this embodiment, the solar module 100 includes a front layer 105, an impact cushion layer 110, a solar cell layer 115, a support layer 120, and a back layer 125.

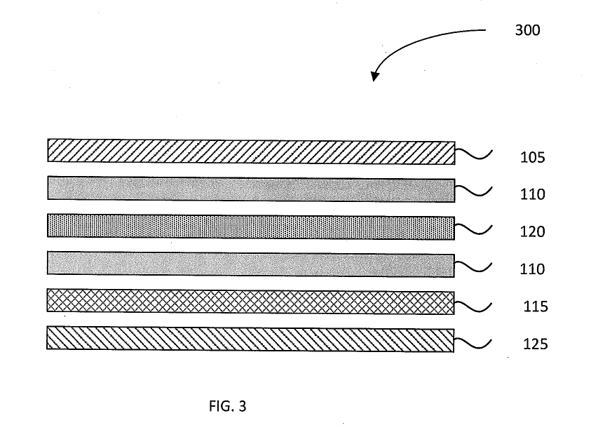

FIG. 2 illustrates another embodiment of a semi-flexible solar module 200. The embodiment of FIG. 2 is similar to that of FIG. 1, except that an additional impact cushion layer 110 has been provided between the solar cell layer 115 and the support layer 120.

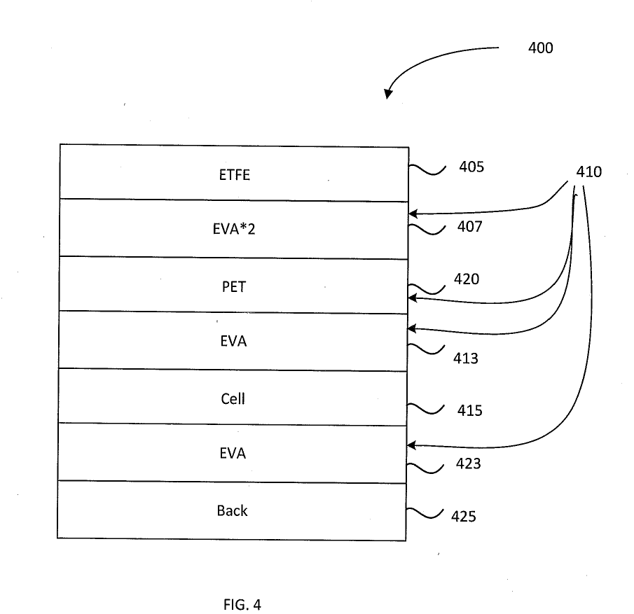

FIG. 3 illustrates a further embodiment of a semi-flexible solar module 300. In this embodiment, the support layer 120 and solar cell layer 115 of FIG. 2 have been switched in position such that the support layer 120 is now above the solar cell layer 115 and between the two impact cushion layers 110. In some cases, placing the support layer 120 above the solar cell layer 115 is intended to enhance the cushion layers to prevent outside impact. In other cases, the solar layer 115 may be placed above as this configuration may improve light transmission being above the support layer.

The front layer 105 is transparent and is intended to provide some protection to the solar module. In particular, the front layer 105 may provide ultra-violet (UV) protection to reduce or prevent sub-layer degradation from sun exposure. The front layer 105 may be made from at least one material selected from a group of ethylene tetrafluorethylene (ETFE), ethylene chlorotrifluoroethylene, polyvinyl fluoride film, ethylene propylene copolymer. The front layer may have thickness between 0.025 to 0.1 mm. Depending on the material chosen, the front layer is intended to provide:
a. superior adhesion to sub-layer (possibly via surface treatment);
b. excellent dielectric strength to help make the front layer 105 an effective insulator;
c. good mechanical strength (tear strength) and dimensional stability;
d. protection against moisture; and
e. low surface energy so the front layer 105 will stay cleaner and can be cleaned easily.

The impact cushion layer 110 is intended to absorb impact energy, such as from hail, snow, wind-borne solid debris, and the like, to prevent damage to the solar cells within the solar cell layer 115. The impact cushion layer 110 may generally be disposed adjacent to the solar cell layer 115. In some cases, the impact cushion layer 110 may be provided on both sides of the solar cell layer 115 to provide for greater protection. In some cases, the impact cushion layer may also serve as an adhesive between the front layer 105 and the solar cell layer 115 and/or between the solar cell layer 105 and the support layer 120 and/or other layers in the stack. The impact cushion layer 110 may be at least one material selected from a group of ethylene vinyl acetate (EVA), silicone sealant, epoxy, polyolefin, butyl rubber based adhesive, or vinyl phenolic.

The solar cell layer 115 is formed from monocrystalline or polycrystalline silicon cells. These silicon cells may be a conventional size, such as 156 mm×156 mm, or may be other sizes of cells that are mounted in the solar cell layer 115. In a solar panel, cells may be connected in series with, for example, a metal ribbon or the like. Each solar cell may be manually or automatically soldered together or may use electrical conductive adhesive to bond the solar cell to the metal ribbon.

The support layer 120 is configured to have sufficient load bearing properties that the supporting layer 120 can support the solar cell layer 115 such that the solar cell layer 115 will not break. As such, the supporting layer 120 may be rigid or semi-flexible and may be fabricated from at least one material selected from a group of polyethylene terephthalate (PET), polyurethane, polyetherimide, polyvinylidene fluorid, ethylene vinyl acetate, polyester, fiber glass sheet, coated dielectric plastic aluminum or stainless steel sheet, carbon fiber reinforced thermoplastic, and glass fiber reinforced thermoplastic. In some embodiments, if the support layer is placed above the solar cells, the support layer, for example, the PET, is intended to be transparent and have a thickness of no more than approximately 0.5 mm. In some cases, the thickness may be approximately 0.25 mm. If the support layer is placed below the solar cell layer, the material may have a thickness between 0.2 mm and 2 mm.

In some cases, the support layer 120 may be transparent and may be placed above the solar cell layer 115. It is intended that placing the support layer 120 above the solar cell layer 115, will provide further protection to the solar cell layer 115 from impacts and the like. As illustrated in FIGS. 2 and 3, in some cases, the support layer 120 may be provided above the solar cell layer 115 and impact cushion layers 110 may be above and below the support layer 120 as well as below the solar cell layer 115 in order to provide for softer layers for impact protection but also include impact protection from the support layer 120.

The back layer 125 is intended to provide different physical or chemical properties offering protection from a wide range of environmental elements. The properties may include for example: mechanical strength, UV resistance, dielectric strength, thermal stability, hydrolytic stability, and moisture resistance. The back layer 125 can be either rigid or semi-flexible and may be selected from tedlar polyester tedlar (TPT), kynar film/PTE/EVA (KPE), Thermoplastic elastomer (TPE), coated aluminum sheet, coated stainless sheet, fiberglass, carbon fiber reinforced thermoplastic, glass fiber reinforced thermoplastic. The back layer 120 thickness may be between 0.5 mm to 3 mm. It will be understood that the crystalline solar cell is fragile while the thin film solar cells may be rolled up. It is intended that the semi-flexible solar panel use crystalline solar cells and may be bent approximately 30 degrees within 1 m length with 800 mm radius curve.

In some cases, the back layer 120 may include a plurality of sub-layers, for example, a PET sub-layer as a middle sub-layer or upper sub-layer and may include a second material for at least one other layer of the back layer 120. The second layer could be fabricated from, for example, polyvinyl fluoride (PVF), or polyvinylidene fluoride (PVDF), a thermoplastic fluoropolymer material which features high water-resistance and inherent strength, has low permeability of moisture, vapor, oil and may be used in a wide temperature range of for example, between −70° C. to +110° C.

In each of the above embodiments, one or more adhesive layers 130 may be provided between the various layers in order to maintain bonding where the layer material itself cannot be used in creating a bond between layers. In some cases, an adhesive layer 130 may also function as an impact cushion layer 110.

In the above embodiments, the semi-flexible solar panel is formed without a glass layer in order to provide flexibility, reduce weight, make the panel less susceptible to breakage and the like. The use of crystalline solar cells is intended to provide improved energy conversion efficiency when compared with thin-film solar cells of the type that are typically used in flexible solar cells.

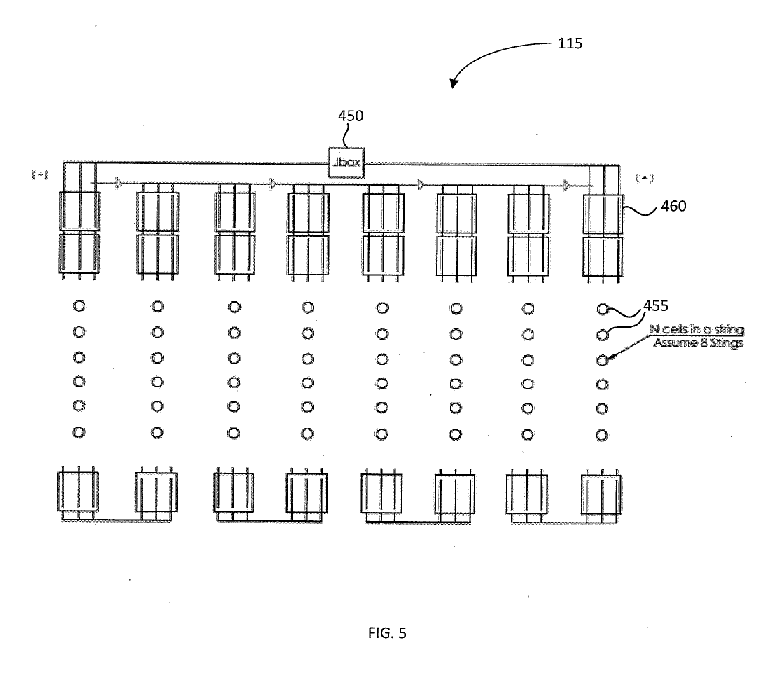

FIG. 4 illustrates another embodiment of a solar module 400. FIG. 4 illustrates specific materials for each of the above noted layers in the solar module 400

In this particular embodiment, the front layer 405 is ethylene tetrafluoroethylene (ETFE), a fluorine-based plastic. The nature of this plastic allows for UV protection and other properties, for example, high transmittance (greater than or equal to 92%), high dielectric strength, which is intended to help make the layer an effective insulator, good mechanical strength and moisture permeability. Those properties may be needed for the front layer. The front layer 405 may be followed by a first adhesive layer 407 of ethylene-vinyl-acetate (EVA) for bonding to a support layer 420. In some cases, the first adhesive layer 407 may include two or more sub-layers of ethylene-vinyl-acetate (EVA). In this embodiment, the first adhesive layer 407 may also serve as an impact cushion layer 410.

The support layer 420 is polyethylene terephthalate (PET). In this case, the support layer 420 may also act as an impact cushion layer 410. A second adhesive layer 413 (also formed of EVA) then adheres the support layer 420 to the solar cell layer 415. A third adhesive layer 423 (also formed of EVA) adheres the solar cell layer 415 to the back layer 425. The second and third adhesive layers 413, 423 and may also serve as further impact cushion layers 410 for the solar cell layer 415.

The back layer 120 may be formed of Toyal FPL which may have an approximate thickness of 0.375 mm. FPL is intended to have high tensile strength, dimensional stability, and low permeability of water vapor. In this example, an ETFE layer may be about 0.05 mm, an EVA layer may be between 0.45 mm and 0.5 mm, a PET layer may be about 0.25 mm, the solar cell layer may be 0.20 mm and a back layer, which may be FPL, TPT or KPE may be about 0.375 mm.

Generally, the embodiments of the semi-flexible solar module described herein are made without glass in order to allow the solar module to have some degree of flexibility. Further, the solar module generally does not require an aluminum frame which may be approximately 40 to 50% of a conventional module's weight. For example, a conventional solar module's weight loading may be approximately 11 kg/M², whereas the semi-flexible solar module provided herein is intended to have a weight loading of approximately 4 kg/M² to 5 kg/M². In some specific cases, the weight loading may be approximately 4.6 kg/M². The solar module is intended to include a combination of high efficiency, low cost crystalline silicon cells with a lightweight, rigid or semi-flexible substrate structure. In some cases, it is intended that the semi-flexible structure would allow for approximately 30 degree solar module bending. The total module thickness is intended to be between 2 mm to 8 mm. In some particular cases, the solar module thickness may be between 3 mm to 5 mm.

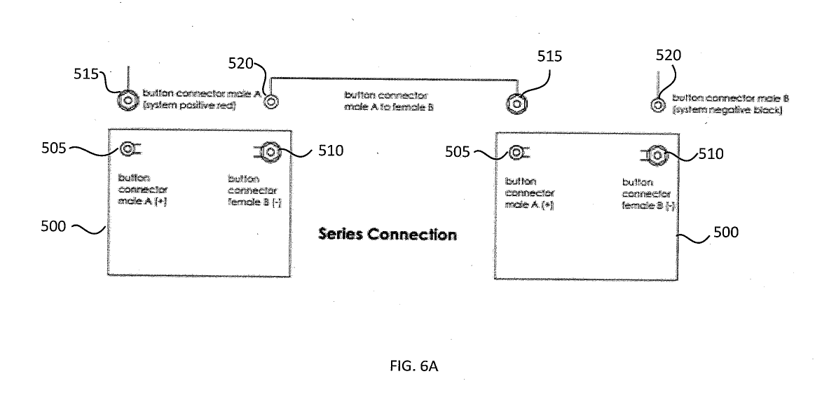

FIG. 5 illustrates a solar cell layer 115 in further detail. As shown in FIG. 5, the solar cell layer 115 will include a plurality of solar cells and bus bars that extend across the solar cells on both sides in order to interconnect the solar cells and allow electricity to flow from and through the solar cells as it is produced. The bus bars may be provided to the solar cell layer 115 by any conventional method, for example, by conventional soldering techniques, either manually or automatically. In other cases, the bus bars may be bonded to the solar cell layer 115 by electrically conductive adhesive (ECA). In at least some cases of the present embodiments, the bus bars will be covered by, for example, the impact cushion layer 110 and the front layer 105 during the lamination process.

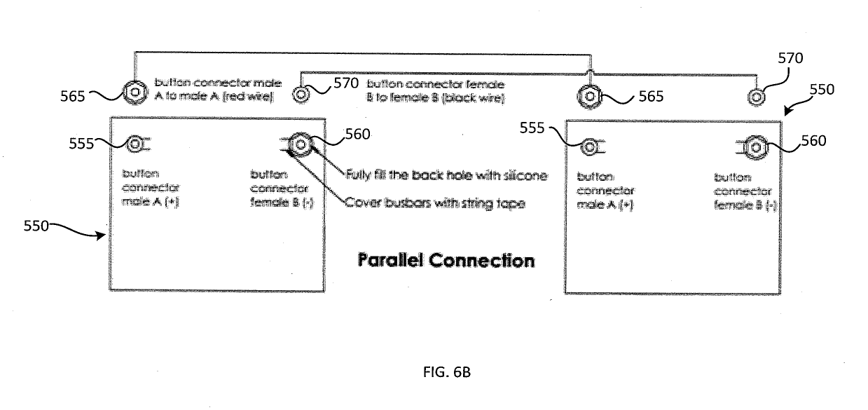

FIG. 6A illustrates low profile button connectors 500 in series connection according to an embodiment herein. The button connector 500 includes a socket 510 and a stud 505 that are installed on a front or back side of the solar module 100 respectively. As shown in FIG. 6, the button connector 500 is embedded in the layers of the solar module. The socket 505 and stud 510 each make contact with the bus bars, and in particular the male connector 520 and female connector 515 on the bus bar on their respective sides of the solar module. Solar modules may then be connected by press fitting the stud 510 into the socket 505 as illustrated in FIG. 6A or use additional connection cable to be connected together.

FIG. 6B illustrates low profile button connectors 550 in parallel connection. Similarly to FIG. 6A, FIG. 6B includes a male stud 555 and female socket 560 located on the solar module and configured to connect via press fitting to be connected together in a parallel manner to corresponding connectors, 565 and 570. It will be understood that the connectors will be fully filled in order to ensure that there is no hole. In some cases the filler may be silicone or similar material. The bus bars may be covered with string tape to be insulated to prevent touching from other conductive material which may cause an electrical short.

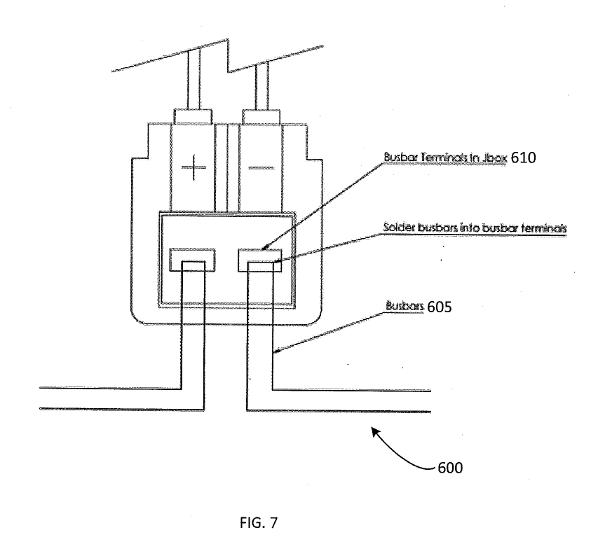

FIG. 7 illustrates a junction box 600 provided to a bus bar 605 on the solar cell layer 105. The bus bars 605 may connect to a junction box terminal 610 by, for example, soldering. If the module power is equal to or no more than 100 W, the junction box may contain one bypass diode. If the module power is above 100 W, the junction box may not contain bypass diode, but the bypass diodes may instead be integrated into the solar module.

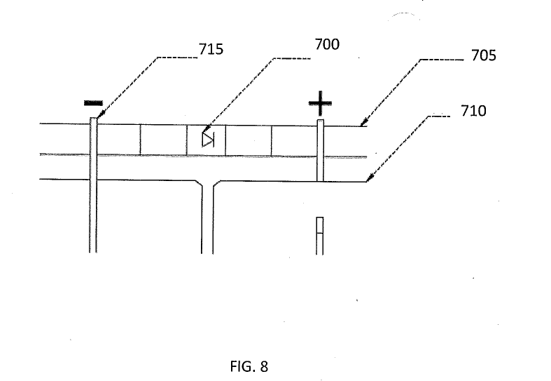

FIG. 8 illustrates the provision of one or more diodes 700 on a bus bars 705 in an alternative embodiment. The one or more diodes 700 are bypass diodes, which are intended to protect the solar cells 710 from hot-spot risk, such as, for example, when there is shade or some type of damage to one or more of the solar cells 710, wherein the solar cells 710 are connected to the bus bars 705 via conductive ribbon 715. Typically one bypass diode is provided per string of solar cells. In a conventional solar module, the bypass diodes are provided in the junction box. However, in at least some embodiments herein, the bypass diodes are provided directly on the bus bars and are included in the lamination of the various layers of the solar module.

Conventional bypass diodes used in cell based solar panels may serve as a protection mechanism that allows the panel to continue producing power even if one or more of its cell strings is not working, for example, shaded, damaged, or the like. Typically, all strings may be connected in series and each cell attempts to produce current in direct proportion to the amount of sunlight it receives. If any of the cells begin to function at a reduced capacity, for example, the cell is shaded, soiled, damaged or the like, the entire string current may be limited to that which the weakest cell can support. In these conditions, the panel does not operate at full power.

A typical cell may have a forward voltage of approximately 0.5V when optimally loaded. If the cell is, for example, shaded, the cell may not produce as much current as other nearby cells, then the cell may be forced into a reverse mode of operation where it is subjected to negative voltage. The underperforming cell may become a heating element, creating a hot sport on the solar module which may damage the solar module. In order to prevent these issues, it is intended that a series of cells of the solar module be arranged in string and a bypass diode may be connected in parallel to each string.

The connectors are intended to use low profile and compact form factors to be integrate into the solar module. In some cases the thickness may be approximately 0.7 mm which is intended to make the lamination process easier and smoother than traditional processes. The solar module thickness is intended to be between 3 mm to 5 mm. The diodes may be soldered with the bus bar between two strings. With integrated diodes, it may be feasible to use more diodes per solar module, allowing the remaining substrings to continue to produce in partial shaded conditions.

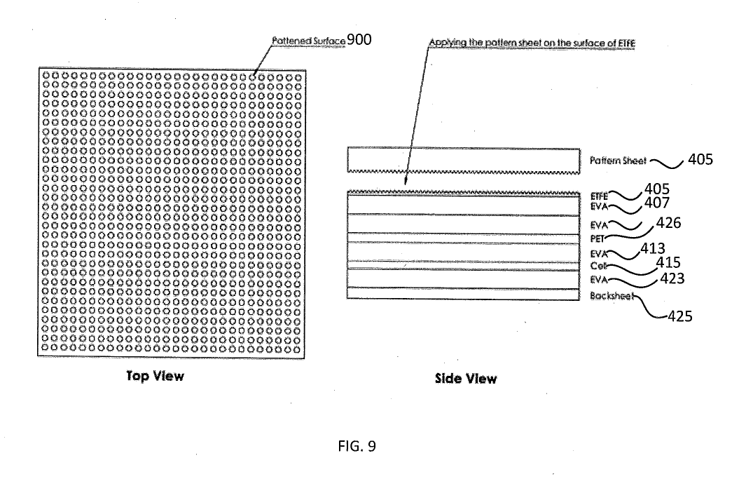

In some embodiments, the solar module may be configured to include a surface pattern 900 on the front layer 405 as shown in FIG. 9, which illustrates a pattern sheet on the surface of the solar module shown in FIG. 4. The surface pattern 900 may be created mechanically or through, for example, pressure treating the front layer 405. The surface pattern 900 is intended to prevent surface wrinkles during module processing and reduce sun reflective loss and increase module output efficiency. In some conventional solar modules, severe surface wrinkling has been observed. The embodiments of the solar module herein may include a special pattern sheet applied to the surface of the front layer 405, for example during module processing, which is intended to provide consistent surface angle contact due to a predetermined profile. The predetermined profile can be one of various patterns, including dimple pattern, triangle pattern, rectangle pattern, square pattern, and linear cross-hatching pattern. The pattern depth is preferably between 0.05 mm to 0.5 mm. By providing a cross-hatching pattern sheet on the front layer 405 of the solar module, it was noted that there was either a reduction or an elimination of the surface wrinkle and the solar module was able to maintain light penetration efficiency of more than 90%. The surface pattern sheet can be selected from one of group from high temperature pattern plastic, cross-hatching fiber Teflon sheet, textured fiberglass, coated metal sheet.

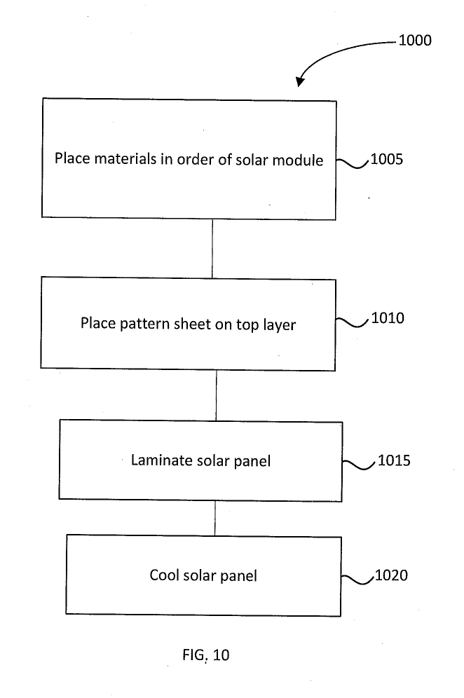

FIG. 10 illustrates a method for applying a pattern sheet to a solar module. At 1005, materials are placed in order to create a solar module. At 1010, a pattern sheet is placed onto the top layer of the solar module. At 1015, the solar panel is sent to a laminator. The lamination process may include vacuum, for example for 3 to 8 minutes, followed by retaining for a period of, for example, 10 to 18 minutes with press pressure of approximately 60 to 85 kpa and at a temperature of approximately 145 to 155° C. At 1020, the solar module may be cooled after it is removed from the laminator. In some cases a heavy flat plate or similar object may be placed on top of the pattern sheet for a period of time to maintain the pattern shape during the cooling. The module may sit on an unloading convey to cool down after lamination. In some cases a heavy flat plate or similar object may be placed on top of the pattern sheet for a period of time in order to maintain pattern shape and to prevent module warping during the cooling

The local surface treatment is intended to increase surface energy leading to superior bonding strength to junction box or other connector touching the surface. The local surface can be treated by one of techniques like corona (under O₂/N₂, N₂, N₂/CO₂, or the like), flame treatment, atmospheric plasma activation, and atmospheric or low pressure plasma deposition.

In the preceding description, for purposes of explanation, numerous details are set forth in order to provide a thorough understanding of the embodiments. However, it will be apparent to one skilled in the art that these specific details are not required. In other instances, well-known electrical structures and circuits are shown in block diagram form in order not to obscure the understanding. For example, specific details are not provided as to whether the embodiments described herein are implemented as a software routine, hardware circuit, firmware, or a combination thereof.

The above-described embodiments are intended to be examples only. Alterations, modifications and variations can be effected to the particular embodiments by those of skill in the art without departing from the scope, which is defined solely by the claims appended hereto.

1. A semi-flexible solar module comprising:
a front layer comprising an ultra-violet reflecting material;
one or more impact cushion layers;
a solar cell layer comprising crystalline silicon solar cells;
a support layer comprising a semi-flexible material configured to support the solar cell layer; and
a back layer,
wherein none of the layers is formed of glass.

2. A semi-flexible solar module according to claim 1 wherein the support layer is transparent and positioned between the front layer and the solar cell layer.

3. A semi-flexible solar module according to claim 1 wherein the one or more impact cushion layers also functions as an adhesive layer.

4. A semi-flexible solar module according to claim 1 further comprising a second impact cushion layer between the solar cell layer and the support layer.

5. A semi-flexible solar module according to claim 1 further comprising one or more adhesive layers between the noted layers.

6. A semi-flexible solar module according to claim 1 further comprising a bypass diode provided to a bus bar on the solar cell layer.

7. A semi-flexible solar module according to claim 6 wherein the bypass diode comprises a plurality of bypass diodes provided to different bus bars on the solar cell layer.

8. A semi-flexible solar module according to claim 1 wherein the thickness of the module is between 3 mm and 5 mm.

9. A semi-flexible solar module according to claim 1 wherein the module further comprises low profile button connectors.

10. A semi-flexible solar module according to claim 1, wherein the front layer comprises a surface pattern.

11. A semi-flexible solar module according to claim 10, wherein the surface pattern has a pattern depth between 0.05 mm to 0.5 mm.

12. A semi-flexible solar module comprising:
a front layer formed of ETFE;
a plurality of impact cushion layers formed of EVA;
a solar cell layer formed of crystalline silicon solar cells;
a support layer formed of PET; and
a back layer formed of TPT.

13. A semi-flexible solar module according to claim 12 wherein the support layer is transparent and positioned between the front layer and the solar cell layer.

14. (canceled)

15. A semi-flexible solar module according to claim 12 further comprising a second impact cushion layer between the solar cell layer and the support layer.

16. (canceled)

17. A semi-flexible solar module according to claim 12 further comprising a bypass diode provided to a bus bar on the solar cell layer.

18. (canceled)

19. (canceled)

20. A semi-flexible solar module according to claim 12 wherein the module further comprises low profile button connectors.

21. A semi-flexible solar module according to claim 12 wherein the front layer comprises a surface pattern.

22. (canceled)

23. A method for applying a pattern sheet to a solar module comprising:
placing solar module layers in order to create the solar module;
placing a pattern sheet on a top layer of the solar module;
laminating the solar module; and
cooling the solar module.

24. A method according to claim 23 wherein the lamination of the solar module comprises:
providing a vacuum to the solar module; and
providing a retaining period to the solar module.

25. A method according to claim 23, wherein the retainer period is 10-18 minutes in duration at a press pressure of 60 to 85 kPa and at a temperature of 145° C. to 155° C.

26. (canceled)
